(19) United States
(12) Patent Application Publication
(10) Pub. No.: US 2007/0117248 A1
(43) Pub. Date: May 24, 2007

(54) Method for the production of light-emitting semiconductor diodes

(76) Inventors: Jochen Kunze, Moers (DE); Veit Schwegler, Stuttgart (DE); Thorsten Ricking, Laudenbach (DE); Thomas Manth, Aachen (DE); Cem Olkay, Witten (DE)

Correspondence Address: CLARK HILL, P.C., 500 WOODWARD AVENUE, SUITE 3500, DETROIT, MI, 48226, US

(21) Appl. No.: 10/582,311

(22) PCT Filed: Dec. 3, 2004
(86) PCT No.: PCT/DE04/02652

§ 371 Date: Jun. 9, 2006

(30) Foreign Application Priority Data
Dec. 9, 2003 (DE) DE 103 57 818.8
Jul. 9, 2004 (DE) DE102004033533.8

(51) Int. Cl. H01L 21/00

(52) U.S. Cl. 438/57

(57) ABSTRACT

A method is disclosed for creating a light assembly including a light-emitting diode and a printed circuit board having conductors printed thereon. The method includes the steps of positioning the light-emitting diode on the printed circuit board. Once positioned, the light-emitting diode is connected to the printed circuit board. The light-emitted diode and the printed circuit board are positioned in a mold. A thermoplast is injected into the mold such that the thermoplast extends on both sides of the printed circuit board and over the light-emitting diode.

### BACKGROUND ART

1. Field of the Invention

The invention relates to a process for the production of at least one light-emitting semiconductor diode on a printed circuit board. More particularly, the invention relates to production of a light-emitting semiconductor diode on a printed circuit board with an optical element affixed thereto.

2. Description of the Related Art

A light-emitting semiconductor diode, e.g. a light-emitting diode or a laser diode, customarily includes an electrical part and a light distributing body which encircles the electrical part at least in certain areas and is at least substantially transparent. Luminescent diodes of this type are used in lights for automobiles, for room lighting, in light modules for communication, in street lights, and the like.

A lighting unit can include several light-emitting semiconductor diodes (“light-emitting diodes”) produced on one printed circuit board. The component designated here as printed circuit board can be resistant to bending or susceptible to bending. It can also have the form of foil, where the foil can be resistant to bending or susceptible to bending.

A process for the production of light-emitting diodes is known from JP 61 001 067 A. For the formation of the light distribution body in the resin-molding process, the light-emitting chip placed on the printed circuit board is molded around with a resin which penetrates the narrow through holes in the printed circuit board. On drying of the resin, there is a strong shrinkage of the material, whereby the geometry of the light distribution body changes. With this process therefore, only geometrically simple light-emitting diodes can be produced. In addition, the tensile strength of the resin is low. During production as well as during operation, e.g., with a high-power light-emitting chip, mechanical stresses can thus appear. For example, the light distribution body breaks apart. And the light unit fails.

The problem underlying the present invention is to develop a process for reproducible production of a high-power light-emitting semiconductor diode on a printed circuit board as well as a corresponding lighting unit with integrated printed circuit board.

### SUMMARY OF THE INVENTION

A method is disclosed for creating a light assembly including a light-emitting diode and a printed circuit board having conductors printed thereon. The method includes the steps of positioning the light-emitting diode on the printed circuit board. Once positioned, the light-emitting diode is connected to the printed circuit board. The light-emitted diode and the printed circuit board are positioned in a mold. A thermoplast is injected into the mold such that the thermoplast extends on both sides of the printed circuit board and over the light-emitting diode.

### BRIEF DESCRIPTION OF THE DRAWINGS

Advantages of the invention will be readily appreciated as the same becomes better understood by reference to the following detailed description when considered in connection with the accompanying drawings, wherein:

FIG. 1 is a partial cross-sectional side view of one embodiment of the invention;

FIG. 2 is a partial cross-sectional side view of a second embodiment of the invention having a chip carrier secured thereto;

FIG. 3 is a side view of the invention with an optical lens;

FIG. 4 is a side view of the invention with a premounted chip carrier;

FIG. 5 is a partial cross-sectional side view of the embodiment of FIG. 4;

FIG. 6: light-emitting diode with two bond wires,

FIG. 7 is a perspective view of the invention;

FIG. 8 is a partial cross-sectional side view of one embodiment of the invention with a light guide secured thereto;

FIG. 9 is a cross-sectional longitudinal view of the invention;

FIG. 10 is a partial cross section of the invention according to FIG. 9;

FIG. 11 is a partial plan view of the invention according to FIG. 9;

FIG. 12 is a cross-sectional longitudinal view of the invention with a grid-like printed circuit board;

FIG. 13 is a partial cross section of the invention according to FIG. 12; and

FIG. 14 is a partial plan view of the invention according to FIG. 12.

### DETAILED DESCRIPTION OF THE PREFERRED EMBODIMENT(S)

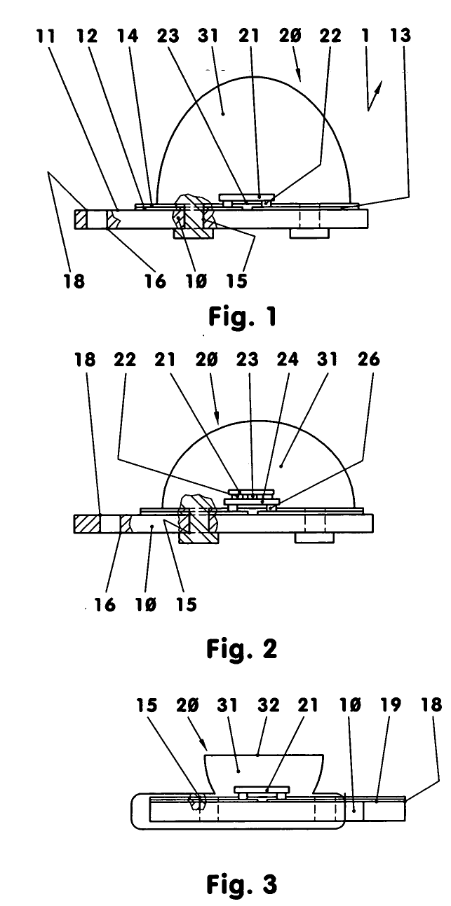

FIG. 1 shows an individual light-emitting diode 20 which is produced on a printed circuit board 10. This light-emitting diode 20 is one of a plurality of light-emitting diodes 20 which are mounted on a common printed circuit board 10 in such a manner that they cannot be removed.

The printed circuit board 10 is a bend-resistant panel, made of plastic or a composite built up of electrically non-conducting materials, on whose upper side 11, or underside, electrical printed conductors 12, 13 are applied. The printed conductors 12, 13 are coated at least in certain areas with a passivation layer 14. The printed circuit board 10 can also be a metal printed circuit board on whose insulated surface printed conductors can be laminated.

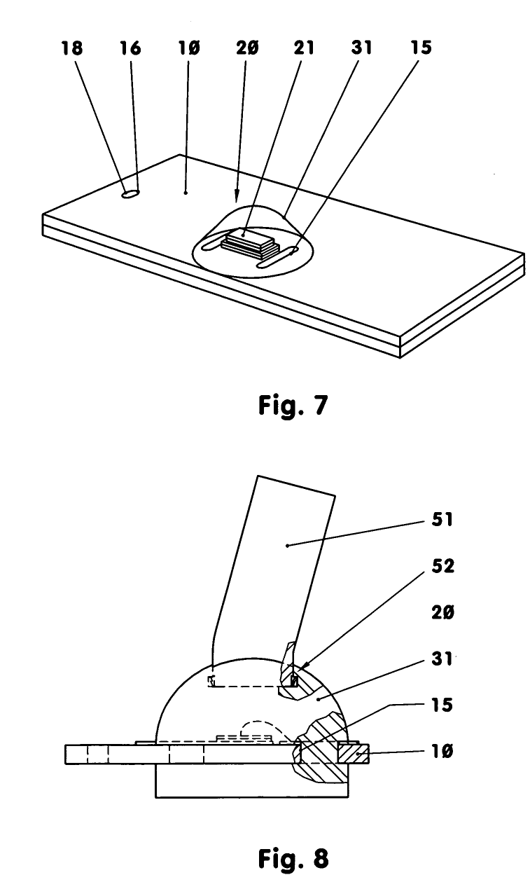

In the printed circuit board 10, three through holes 15, 16 are disposed. Two through holes 15 lie in the area of the printed conductors 12, 13 while one through hole 16 lies outside of the printed conductors 12, 13. The distance of the two through holes 15 from one another corresponds to the distance of the through hole 15, represented here on the left, from the through hole 16. The through holes 15, cf. FIG. 7, are long holes which penetrate the printed conductors 12, 13 and the printed circuit board 10. They are disposed so as to be parallel to one another. The through hole 16 is also a long hole which lies parallel to the long holes 15 and is approximately half as long as they are. The bounding edge of the long hole 16 lying on the upper side 11 is an alignment edge 18.

For the production of the light-emitting diode 20, a light-emitting semiconductor chip 21 is placed on the thus prepared printed circuit board 10. During the placement its position is aligned to the alignment edge 18. The light-emitting semiconductor chip 21 is fastened to the printed conductors 12, 13 with electrically and thermally conducting adhesive and/or solder connection 22 at the points which are free of the passivation layer 14. Instead of a single light-emitting semiconductor chip 21, a group of light-emitting semiconductor chips 21 can also be placed on the printed circuit board 10 and connected with the printed conductors 12,13 in such a manner that the connection is electrically and thermally conducting. The component designated here as light-emitting semiconductor chip 21 can also include a group of individual light-emitting semiconductor chips. In addition, other electrical components, such as resistors, capacitors, etc. can be integrated. It can include a plurality of electrical connections. The assembled printed circuit board 10 can now, through connection of the printed conductors 12, 13 to a direct current source, be tested electrically.

In the next step of the process the light distribution body 31 is produced. For this, the assembled printed circuit board 10 is introduced into an injection mold which is not represented. Here, the upper side 11 of the printed circuit board 10 with the light-emitting semiconductor chip 21 points downward. On introduction into the injection mold, the printed circuit board 10 is laid on and aligned, with the alignment edge 18, to a counter contour of the injection mold.

After closing the injection mold, a thermoplast, e.g. PMMA, is injected into the cavity of the injection mold. The air in the mold will be expelled and/or suctioned off. The cavities of the mold are filled with thermoplast. In given cases, the interstice 23 between the light-emitting semiconductor chip 21 and the printed circuit board 10 is first filled with another material. The thermoplast penetrates through the through holes 15 of the printed circuit board 10 and engages behind the printed circuit board 10. The injection mold is shaped in the form of the light distribution body 31 on the printed circuit board 10. The light distribution body 31 thus produced has the form of a half ellipsoid. It is homogeneous and highly transparent. By the engagement behind, the light-emitting diode 20 is connected, in a fixed manner, to the printed circuit board 10 and can be removed from it only with destruction.

After the production of the light distribution body 31, the electrical printed conductor 12, 13 project, e.g. in the radial direction, over the light distribution body 31. The light-emitting diode 20 thus produced can now be withdrawn from the injection mold. On drying and cooling, the form of the light distribution body 31 essentially does not change at all.

It is subsequently possible to injection-mold around the light-emitting diodes 20 on the printed circuit board 10 once again in an additional processing step. The processing steps can be spatially and/or temporally separated. Here an optical lens can be formed on the light-emitting diode 20. In a sequence of processing steps of this type, a standard module can be produced in the first injection molding step, which then obtains its final form in the second injection molding step.

With this process, a light-emitting diode 20 with high power can be reproducibly produced on a printed circuit board. In so doing, a homogeneous light distribution body arises, whose form does not change after its withdrawal from the injection mold. Furthermore, a plurality of forms of the light-emitting semiconductor diode can be realized with this process. The light distribution body 31 can have backcuts, only capable of being produced by injection-molding process, and can include an optical lens, a surface of free form, a diffraction surface, or a fractional surface.

FIG. 2 shows a light-emitting diode 20 with a chip carrier 24. The chip carrier 24 can be a heat insulator, a reflector, a heat sink, and the like. It can also be built up in multiple layers. Thus, the chip carrier 24 can include a thermal insulation layer on which a reflective layer is applied. The chip carrier 24 can also have electrically conducting areas.

In the production of the light-emitting diode 20 on the printed circuit board 10 the light-emitting semiconductor chip 21 is first placed on the chip carrier 24 and connected with an electrical and thermally conducting adhesive and/or solder connection 22 to an electrically conducting area of the chip carrier 24.

The light-emitting semiconductor chip 21 is then mounted together with the chip carrier 24 on the printed circuit board 10 and aligned to the alignment edge 18. An electrically and thermally conductive adhesive and solder connection 26 between the chip carrier 24 and the printed circuit board 10 is produced to electrically connect the light-emitting semiconductor chip 21 to the printed circuit board 10.

The assembled printed circuit board 10 is then, as described in the first embodiment example, introduced into an injection mold, aligned by means of the alignment edge 18, and injected around.

FIG. 3 shows a light-emitting diode 20 with an integrated optical lens 32. Here, the printed circuit board 10 has two alignment edges 18, 19. The alignment edges 18, 19 are two outer edges of the printed circuit board 10 which are disposed so as to be perpendicular to one another.

In the mounting of the light-emitting semiconductor chip 21 on the printed circuit board 10, the position of the light-emitting semiconductor chip 21 is aligned to the printed circuit board 10 using the alignment edges 18, 19.

If the printed circuit board 10 assembled with the light-emitting semiconductor chip 21 is introduced into the injection mold, it is aligned, e.g. with the alignment edges 18, 19, to the counter contour of the injection mold.

On introduction of the thermoplast into the injection mold, the thermoplast flows around the printed circuit board 10 and penetrates the through holes 15. The light distribution body 31 produced in the injection molding, here represented above the printed circuit board 10, can be formed to have the structure of an ellipsoidal frustum whose upper side includes an optical lens 32. The diameter of this ellipsoidal frustum grows constantly from the printed circuit board 10 out in the direction of the optical lens 32. The maximum diameter of the ellipsoidal frustum corresponds to the diameter of the optical lens 32 and is approximately twice its height. Its minimum diameter near the printed circuit board 10 is approximately 80% of this diameter.

Here the optical lens 32 is a plane lens which is integrated into the light distribution body 31. However, the optical lens 32 can also have the structure of a convergent lens, a divergent lens, a prism face, a face of free form, a fractional face, a diffraction face, and the like.

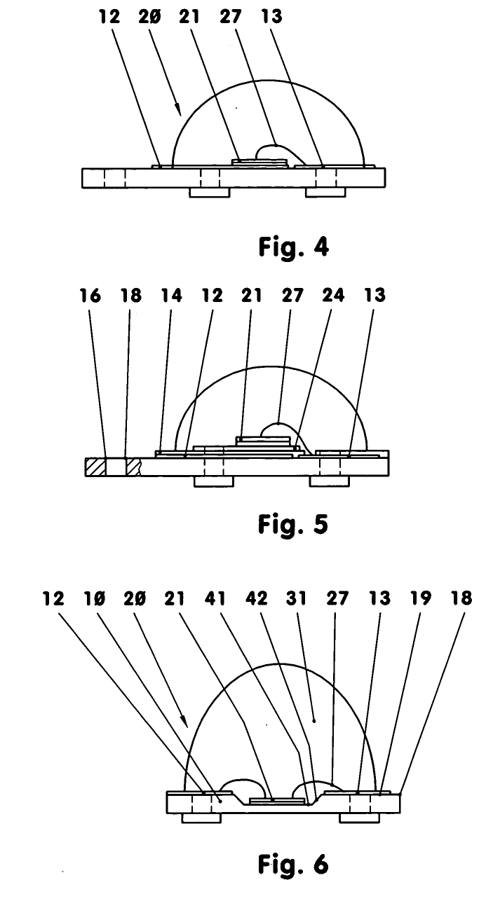

The light-emitting diodes 20 represented in FIGS. 4 and 5 are produced in a manner similar to that of the light-emitting diodes 20 which are shown in FIGS. 1 and 2. In some instances, the light-emitting semiconductor chip 21 is premounted on a chip carrier 24, set on the printed circuit board 10, and aligned to the alignment edge 18.

In these embodiment examples, the light-emitting semiconductor chip 21 is fastened only to one printed conductor 12 with an adhesive and solder connection 22. The other electrical printed conductor 13 is connected electrically via a bond wire 27 to the light-emitting semiconductor chip 21. In FIG. 6 a light-emitting diode 20 is represented in which the light-emitting semiconductor chip 21 is connected to the printed conductors 12, 13 by means of two bond wires 27.

The light-emitting semiconductor chip 21 is introduced into a hollow 41 of the printed circuit board 10 which is coated with a reflecting layer 42. On introduction of the light-emitting semiconductor chip 21 its position is aligned using the two alignment edges 18, 19.

FIG. 8 shows a light-emitting diode 20 with a light guide 51. The light guide 51 can be rigid or flexible. It is fastened in the light distribution body 31 with a clip connection 52, formed onto it, and the like. Also, other form-locking and/or force-locking connections are conceivable.

In the production of this light-emitting diode 20, the material of the light distribution body 31 penetrates the two through holes 15. The light distribution body 31 engages behind the printed circuit board 10 and lies with its full surface on the printed circuit board 10, on one side of the printed circuit board 10, specifically the side facing away from the light-emitting semiconductor chip 21.

The alignment edge 18 can be an edge of an alignment face. This alignment face can be the inner wall of a wedge-like or cylindrical hole, the wall of a cylinder, the outer surface of the printed circuit board 10, the wall of a cylindrical pin, and the like.

On introduction of the printed circuit board 10 assembled with the light-emitting semiconductor chip 21 into the injection mold, the light-emitting semiconductor chip 21 is aligned with respect to the injection mold. Here, the light-emitting semiconductor chip 21 can be disposed so as to be normal to the optical axis of the light distribution body 31 to be produced, in or near the origin of the contour of the light distribution body 31, and the like. The origin is a prominent point in relation to a physical property or a geometrical boundary condition for the description of the contour of the light distribution body 31.

On introduction of the printed circuit board 10 assembled with the light-emitting semiconductor chip 21 into the injection mold, the light-emitting semiconductor chip 21 can lie below, above, or to the side of the printed circuit board 10. In the injection molding, the thermoplast can be fed from the side of the light distribution body 31, from the underside of the printed circuit board 10, or from the side.

The thermoplast can flow around a printed circuit board 10, which includes no through holes 15. The finished light distribution body 31 then engages around the printed circuit board 10.

The printed circuit board 10 can be built up in multiple layers. They can have several printed conductors 12, 13. In addition, they can include a metal core for discharging heat of the light-emitting semiconductor chip 21, include a coating, and the like.

The printed circuit board 10 can be a foil, onto which printed conductors 12, 13 are applied. An alignment edge 18 is then, for example a limiting edge of the foil, a punched-through hole, and the like.

The light-emitting chip 21 or a group of light-emitting chips 21 can have three or more electrical connections in all the forms of embodiment represented. They can be electrically and/or thermally conductive adhesive connections 22, bond wires 27, and the like. Also, combinations of electrical connections of different types are conceivable. The light-emitting diode 20 can then, depending on the electrical connection, illuminate at different levels of brightness or in different colors.

The thermoplast has a low optical damping. The light-emitting diodes 20 produced with the process and produced on a printed circuit board 10 have small size and high light output.

In the production of several light-emitting diodes 20 on one printed circuit board 10, the thermoplast can be introduced in one common injection mold. The injection mold can then include a single sprue for each individual light distribution body 31. However, several, or all, of the light distribution bodies 31 can be produced by injection molding via a common sprue.

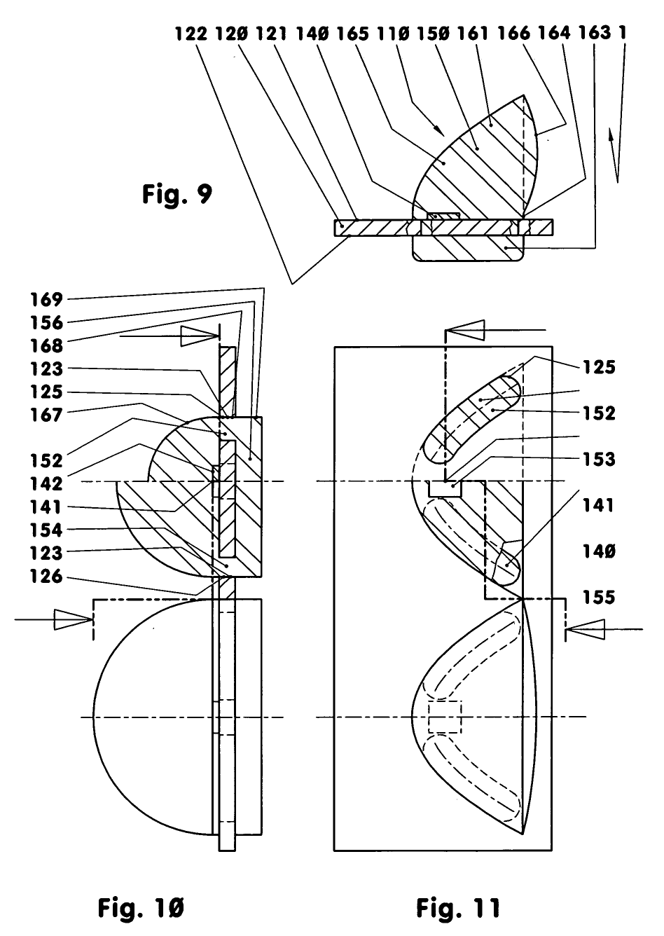

FIGS. 9 to 11 show a lighting unit 110 with an integrated printed circuit board 120. On the printed circuit board 120 sit two light-emitting chips 140. Each of these light-emitting chips 140 is encircled by a light distribution body 150 fastened to the printed circuit board 120. A light distribution body 150 can also encircle several light-emitting chips 140, e.g. a group of light-emitting chips 140.

The component designated here as printed circuit board 120 can be a foil which is subject to bending or resistant to bending, a plate made of fiber-reinforced plastic or built up from electrically non-conductive composite material, a metal printed circuit board with insulated surface, a ceramic printed circuit board, and the like. On its assembly side 121 on which the light-emitting chip 140 is disposed and/or on its unassembled side 122, electrical printed conductors, not represented here, are applied or laminated.

The printed circuit board 120 includes four through holes 123. These through holes 123 are long holes 125, 126 which are curved in the form of a parabola and whose width is approximately one fourth of their length. The width of the long holes 125, 126 is greater than the length of the diagonals of one of the light-emitting chips 140 represented here as square. Each two of these long holes 125, 126 are disposed so as to be symmetric to one another, where the respective plane of symmetry contains the midpoint 141 of the surface 142 of a light-emitting chip 140. The printed circuit board 120 can also include three through holes 123, of which two lie so as to be symmetric to the light-emitting chip 140 and the third lies at an arbitrary point in the vicinity of the chip 140. The through holes 123 can also have a rectangular, circular, etc. cross section.

The single light-emitting chip 140 is a semiconductor chip of an inorganic or organic type and can develop a high light intensity. It is connected to the electrical printed conductors of the printed circuit board 120 in such a manner that is electrically conductive. Furthermore, there is a thermally conductive connection between the light-emitting chip 140 and the printed circuit board 120. It can be rectangular, round, hexagonal, etc. in plan view.

The single light distribution body 150 is a completely transparent body which consists of a homogenous thermoplast, e.g. PMMA, polycarbonate, polysulfone, and the like. It includes a light distribution section 161 lying on the assembled side 121 of the printed circuit board 120 and a fastening section 163 lying on the unassembled underside 122. The contours of the application faces of the light distribution body 150 on the two sides 121, 122 of the printed circuit board are congruent to one another and lie against one another.

The light distribution section 161 includes a cylinder 164, a light deflection body 165, and an optical lens 166. Its height normal to the printed circuit board 120 is at least the thickness of the printed circuit board. In the embodiment example the height is approximately five times the thickness of the printed circuit board.

The cylinder 164 stands perpendicular to the printed circuit board 120. Its generating curve, which lies in a plane parallel to the printed circuit board 120, is composed of a parabolic section and a straight line. The length of the cylinder 164 corresponds to the height of the light-emitting chip 140. The light-emitting chip 140 lies with its midpoint 141 on the normal at the focal point of the parabolic section.

The light deflection body 165 has the structure of a half-paraboloid, e.g. a paraboloid of rotation or an elliptical paraboloid. It stands on the cylinder 164, where the respective surfaces make a transition into one another. The midpoint 141 of the surface 142 of the light-emitting chip 140 lies at the focal point of the half-paraboloid. The light deflection body 165 includes an optical lens 166 standing approximately perpendicular to the printed circuit board 120. This optical lens 166 can be a convergent lens, a divergent lens, and the like. The light distribution section 161 can be embodied without a light deflection body 165. It can include a simple optical lens.

The fastening section 163 includes a plate-like wraparound 156. This has a constant material thickness, which corresponds to the thickness of the printed circuit board 120. In given cases, tabs can also be disposed on the fastening section 163, said tabs projecting in the direction normal to the underside 122 of the printed circuit board.

The light distribution section 161 and the fastening section 163 are connected to one another by means of two feedthrough links 152, 154, each of which projects through a long hole 125, 126 of the printed circuit board 120. The feedthrough links 152, 154 are disposed so as to be symmetric to one another, where the plane of symmetry contains the midpoint 141 of the light-emitting chip 140.

If the printed circuit board 120 includes several through holes 123 in the vicinity of the light-emitting chip 140, the light distribution section 161 and the fastening section 163 can also be connected to one another via several feedthrough links 152, 154.

These feedthrough links 152, 154 have, e.g. along their height normal to the printed circuit board 120—this corresponds to the thickness of the printed circuit board 120—a constant cross-sectional surface 153, 155 which corresponds to the cross-sectional surface of the long holes 125, 126. This cross-sectional surface 153, 155 of a feedthrough link 152, 154 is in the representation of FIGS. 9-11 approximately 28% of the application face with which the light distribution body 150 lies on the assembly 121 of the printed circuit board 120 and on the surface 142 of the light-emitting chip 140. For example, the feedthrough links 152, 154 include at the transitions to the light distribution section 161 and to the fastening section 163 load-relieving hollows.

The cross-sectional surface 153, 155 can vary between 10% and 60% of the above-mentioned application face.

The outer surfaces 167, 168, 169 of the light distribution section 161, of the fastening section 163, and of the feedthrough link 152, 154 have transitions into one another.

Here, the wraparound 156 connects both feedthrough links 152, 154 to one another. The application face of the wraparound 156 on the unassembled side 122 corresponds in the embodiment example represented here approximately to three times the cross-sectional surface 153, 155 of a feedthrough link 152, 154.

The production of the lighting unit 110 is done as described in connection with FIGS. 1-7. First, the punched printed circuit board 120 is assembled with the light-emitting chips 140 and the two parts 120, 140 are connected to one another in such a manner that the connection is electrically and thermally conductive.

The assembled the printed circuit board 120 is now introduced into an injection mold not represented here. The injection openings of the injection mold are located on the unassembled side 122 of the printed circuit board 120 and are aligned in the direction normal to the underside 122. The center of the injection jet then lies in the area below the chip below the geometric center of the through holes 123 within the injection mold.

During injection molding, the injection-molding material flows in the direction perpendicular to the underside 122 of the printed circuit board 120. The injection jet then flows onto the geometric center of the through holes 123, i.e., the center of mass of the through holes 123. There, it strikes the printed circuit board 120, which forms a flow divider for the flow of injection-molding material flowing onto it. The injection-molding material is distributed uniformly on both through holes 123 and builds up the light distribution body 150 on both sides of the printed circuit board 120.

During injection of the thermoplast, the air in the injection mold is expelled and/or suctioned off. The injection mold reproduces the form of the light distribution body 150 on the printed circuit board 120.

In given cases, the injection-molding material can be conducted by means of flow-conducting elevations or indentations on the injection mold and/or printed circuit board 120.

Through the engagement behind, the light distribution body 150 is connected in a fixed manner to the printed circuit board 120 and can be removed from it only with destruction.

The lighting unit 110 thus produced can now be withdrawn from the injection mold. In given cases, the production can also be done in two or more spatially and/or temporally separated manufacturing steps.

On drying and cooling of the light distribution body 150 tensile forces are exerted on the feedthrough links 152, 154. These forces are directed in the direction normal to the assembly side 121 of the printed circuit board 120. The feedthrough links 152, 154 are extended. The extension is however, among other things, due to the large cross-sectional surface 153, 155 significantly less than the strain at break, which for PMMA is 5.5%. The large application face of the wraparound 156 prevents in addition the development of cracks. With further cooling the tensile stresses arising in the material are not relieved and lead to intrinsic stresses in the material. The comparative stress of these intrinsic stresses is significantly less than the elastic limit of the material up to which the material is extended without permanent plastic deformation.

During the operation of the lighting unit 110 each light-emitting chip 140 can be individually electrically controlled. However, all the light-emitting chips 140 can be operated jointly. Also, control of the light-emitting chips 140 in groups is conceivable.

The light radiated from the light-emitting chip 140 is deflected by total reflection in the light distribution body 150 in the direction of the optical lens 166 and radiated through it into the environment 1.

During the operation of the light-emitting chip(s) 140, a great amount of heat arises. A part of this heat is discharged via the thermally conducting connection to the printed circuit board 120. Another part of the heat leads to a heating of the light distribution body 150 and the printed circuit board. The light distribution body 150 and the printed circuit board 120 expand, depending on their coefficients of thermal expansion and differences in temperature.

In the lighting unit 110, the printed circuit board 120 is firmly clamped in the light distribution body 150. If the printed circuit board 120 expands on heating, the light distribution body 150 prevents a deformation of the printed circuit board 120.

On heating of the printed circuit board 120 and/or the light distribution body 150, additional stresses, e.g. as variation in stress, act on the feedthrough links 152, 154. These are then additional tensile stresses which act at least approximately in the same direction as the intrinsic stresses applied due to the production process. The comparison stress of the superposition of these stresses is, due to the large cross section of the individual feedthrough links 152, 154, lower than the elastic limit of the materials. At the same time, the section modulus of the respective cross-sectional faces 153, 155, which is determined by the ratio of the dimensions of the cross-sectional faces 153, 155, prevents a break or a permanent deformation of the feedthrough links 152, 154 due to bending or shearing. Thus, even with an oblique application of force on the feedthrough links 152, 154, e.g. caused by the heating during the operation of the lighting unit 110, no permanent deformation occurs. Likewise, removal of the light distribution body 150 and/or the light-emitting chip 140 from the printed circuit board 120 is prevented by the back-engagement of the light distribution body 150 around the printed circuit board 120. The chip 140 of the light distribution body 150 and the printed circuit board 120 are affixed to one another mechanically so that the alignment of the light-emitting chip 140 to the light distribution body 150. And thus, the optical properties of the lighting unit, are retained long-term.

The light distribution body 150 can have another form on the assembly side 121. Thus, the optical lens 166 can lie parallel to the assembly side 121 or in a plane inclined to the printed circuit board 120. The light distribution body 150 can also have a similar, or the same, form on the two sides 121, 122 of the printed circuit board 120.

Between the light distribution section 161 and the fastening section 163, one or more feedthrough links 152, 154 are disposed. Each of these feedthrough links 152, 154 have a round, rectangular, triangular, trapezoidal, etc. cross-sectional surface 153, 155. The individual cross-sectional surface 153, 155 is then at least 10% of the total of the application face of the light distribution body 150 on the assembly side 121 and the application face of the light distribution body 150 on the light-emitting chip 140.

The fastening section 163 can include several individual wraparounds 156. The application face of each of these wraparounds 156 is then 75% of the cross-sectional surface 153, 155 of the respective feedthrough link 152, 154.

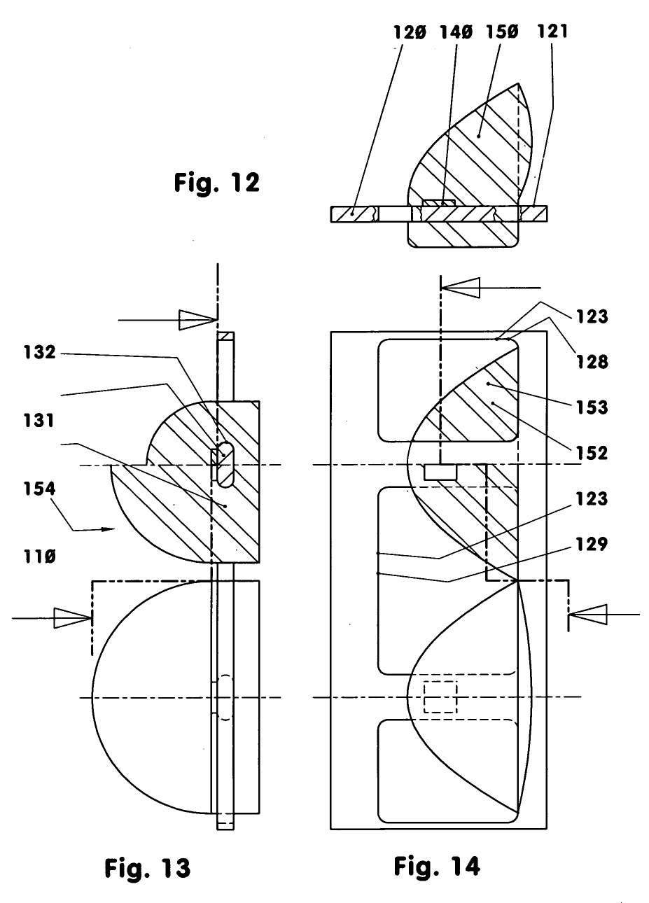

In FIGS. 12-14, a lighting unit with a grid-like printed circuit board 120 is represented. The light distribution body 150 corresponds in its external dimensions to the light distribution body 150 represented in FIGS. 9-11.

The printed circuit board 120, by way of example, is rectangular and includes a frame 124 whose longitudinal sides are connected to one another by printed circuit board links 131. On each of the printed circuit board links 131 a light-emitting chip 140 sits. The frame 124 and the printed circuit board links 131 border the through holes 123.

The cross section of the printed circuit board links 131, cf. FIG. 13, is oval, where the maximum width of the individual printed circuit board links 131 lies in the central longitudinal plane of the printed circuit board 120 parallel to the assembly side 121. The individual printed circuit board link 131 has in this embodiment approximately half again the width of the light-emitting chip 140. The cross section of the printed circuit board link 131 can also be rectangular, triangular, and the like.

The through holes 123 include three approximately rectangular punched holes 128, 129 with rounded corners. The cross-sectional surface of the small punched holes 128 is approximately twice the surface of the printed circuit board links 131 on the assembly side 121. The cross-sectional surface of the large punched holes 129 is approximately four times this surface.

The individual feedthrough link 152, 154 lies on the arched flank 132 of the printed circuit board link 131. Its cross-sectional surface is not constant over the length of the feedthrough link 152, 154. It has at the transition to the light distribution section 161 and to the fastening section 163 a maximum and in the center a minimum. The minimal cross-sectional surface 153, 155 of the feedthrough link 152, 154 in a plane parallel to the assembly side 121 here is approximately 120% of the application surface of the light distribution body 150 on the assembly side 121 of the printed circuit board link 131 and on the light-emitting chip 140.

The two feedthrough links 152, 154 are disposed so as to be symmetric to one another. The plane of symmetry intersects the light-emitting chip 140. The at least approximately triangular cross-sectional surfaces 153, 155 of the two feedthrough links 152, 154 are equally large. Their shortest dimension is, in this embodiment example, approximately 68% of the maximum dimension.

The application face of the light distribution body 150 on the unassembled side 122 of the printed circuit board 120 is in this embodiment approximately 80% of the cross-sectional surface 153, 155 of the individual feedthrough links 152, 154. This installation surface lies opposite the application surface of the light distribution body 150 on the assembly side 121. These external contours of the two installation surfaces are, at least approximately, equally large.

The application face 122 of the light distribution body 150 on the unassembled side of the printed circuit board 120 can be up to approximately 120% of the cross-sectional surface 153, 155 of the individual feedthrough links 152, 154.

The production and the operation of this lighting unit 110 takes place as described in connection with the FIGS. 9-11. Also, in this lighting unit 110 the light distribution bodies 150 are connected to the printed circuit board 120 in such a manner that they are mechanically affixed to one another. A removal of the light distribution body 150 and/or of the light-emitting chip 140 from the printed circuit board 120 is prevented by the feedthrough links 152, 154 as a matter of construction.

The invention has been described in an illustrative manner. It is to be understood that the terminology, which has been used, is intended to be in the nature of words of description rather than of limitation.

Many modifications and variations of the invention are possible in light of the above teachings. Therefore, within the scope of the appended claims, the invention may be practiced other than as specifically described.

1-19. (canceled)

20. A method for creating a light assembly including a light-emitting diode and a printed circuit board having conductors printed thereon, the method comprising the steps of:
positioning the light-emitting diode on the printed circuit board;
connecting the light-emitting diode to the printed circuit board;
positioning the light-emitted diode and the printed circuit board in a mold; and
injecting a thermoplast into the mold such that the thermoplast extends on both sides of the printed circuit board and over the light-emitting diode.

21. A method as set forth in claim 20 wherein the step of injecting the thermoplast includes forcing the thermoplast through a hole in the printed circuit board.

22. A method as set forth in claim 21 including the step of orienting the light-emitted diode below the printed circuit board before positioning the printed circuit board in the mold.

23. A method as set forth in claim 22 wherein the step of positioning the light-emitting diode includes the step of aligning the light-emitted diode with respect to the conductors on the printed circuit board.

24. A method as set forth in claim 23 wherein the step of aligning includes the step of aligning the light-emitted diode with an edge of the hole.

25. A method as set forth in claim 24 including the step of forming an optical lens with the thermoplast.

26. A method as set forth in claim 25 including the step of electrically connecting the light-emitting diode to the printed circuit board with a bond wire.

27. A method as set forth in claim 26 including the step of encasing the bond wire in the thermoplast.

28. A method as set forth in claim 24 wherein the thermoplast forms a light distributing element on the side of the printed circuit board to which the light-emitting diode is connected.

29. A method as set forth in claim 28 including the step of forming a fastening section of the thermoplast on a side of the printed circuit board opposite the side to which the light-emitted diode is connected.
